(19) United States
(12) Patent Application Publication
(10) Pub. No.: US 2002/0064197 A1
(43) Pub. Date: May 30, 2002

(54) Tunable semiconductor laser

(75) Inventors: Craig Tombling, Oxford (GB); Anthony Edward Kelly, Glasgow (GB)

Correspondence Address: LAHIVE & COCKFIELD, 28 STATE STREET, BOSTON, MA, 02109, US

(73) Assignee: KAMELIAN LIMITED, Oxford (GB)

(21) Appl. No.: 09/993,494

(22) Filed: Nov. 28, 2001

(30) Foreign Application Priority Data
Nov. 28, 2000 (GB) 0028949.6

(51) Int. Cl. H01S 5/00

(52) U.S. Cl. 372/45

(57) ABSTRACT

A tunable semiconductor laser comprises a propagation region in which a waveform can exist, the propagation region comprising sequential gain and control regions, the gain region comprising a light amplification region supplied by a source of excitation, and the control region comprising a periodic structure through which the waveform propagates. The control region can be linked to a source of current thereby to enable changes to be made to the refractive index thereof. It is preferred that the material of the propagation region is (Ga,In)(N,As). As a result, in the gain region the waveform will be less tightly confined and hence a higher gain can be produced without suffering from saturation of the gain material. Ideally, there will be tight confinement of the waveform in the control region to allow maximum advantage to be made of the change in refractive index. This can be achieved by controlling the physical configuration of the control region, such as by forming the propagation region with a lesser transverse width in the control region, and/or including non-semiconducting regions to confine the waveform. One way of achieving the latter is to include Al-containing layers in the propagation region; these can be oxidised to produce Al₂O₃.

### FIELD OF THE INVENTION

The present invention relates to a tunable semiconductor laser. These are useful, for example, in dense wavelength multiplexing (DWDM) optical communications systems.

### BACKGROUND OF THE INVENTION

Such networks typically operate around 1.3-1.6μm and require semiconductor lasers and amplifiers. These have to date been effected in III-V semiconductor materials. The present invention is intended to provide a tunable source useful for at least dense wavelength division multiplexing (DWDM) optical systems.

In electronics letters, K de Mesel, vol 36 p1028, active waveguide tapers are made by oxidation of a AlAs containing alloy.

Markus-Christian Amann and Jens Buus, “Tunable Laser Diodes”, Artech House, Norwood Mass. 02062, USA (ISBN 0-89006-963-8) describes the extent of tunable laser diode research and development. In particular, multiple section tunable laser devices are described where the sections include gain sections and grating sections.

In Electronics Letters, M Bachmann, Vol 32 no 22 1996, gain clamped semiconductor optical amplifiers are described which use DBR gratings.

### SUMMARY OF THE INVENTION

The present invention therefore provides a tunable semiconductor laser comprising a (Ga,In)(N,As) propagation region in which an optical waveform can exist, the propagation region comprising sequential gain and control regions, the gain region comprising a light amplification region supplied by a source of excitation, and the control region comprising a periodic structure through which the waveform propagates.

The control region can be linked to a source of current thereby to enable changes to be made to the refractive index thereof. The presence of large numbers of charge carriers affects the refractive index; this in turn changes the effective periodicity as seen by the waveform, and hence the wavelength which is selected by the periodic structure.

The use of the (Ga,In)(N,As) system offers a relatively small difference in refractive index between it and the cladding material, GaAs or other suitable alloy. This index difference is smaller than that obtained in the InP-GaInAsP system most commonly used for these lasers. As a result, in the gain region the waveform will be less tightly confined and hence a higher gain can be produced without suffering from saturation of the gain material.

Ideally, there will be tight confinement of the waveform in the control region. This allows maximum advantage to be made of the change in refractive index resulting from carrier injection. By selecting (Ga,In)(N,As) for the gain region, this will obviate tight confinement by way of materials selection. Accordingly, it is further preferred that the physical configuration of the control region provides for confinement of the waveform therein which is greater than the confinement in the gain region. Tight confinement can be achieved by (for example) physical constraints placed on the control region.

Selection of the (Ga,In)(N,As) system also offers an excellent lattice match with well-characterised GaAs substrates and the opportunity to use Al-oxidation modification processes.

Preferred means of influencing the confinement in the control region are to form the propagation region with a lesser transverse width in the control region. For example, the propagation region could be provided in a ridge structure, the ridge being of lesser width in the control region. Alternatively, the propagation region could include non-semiconducting regions to confine the waveform. One way of achieving this in practice would be to include Al-containing layers in the propagation region. These can be oxidised, such as by exposure to water vapour, to produce a layer containing Al₂O₃. Access for the vapour could be achieved by forming the propagation region in a ridge structure with the edges of the Al-containing layers exposed, or by forming trenches or vias either side of the propagation region. A periodic structure of holes alongside the propagation region will also provide a periodic variation of width in the control region. A combination of these could of course be employed.

The use of controlled oxidation of Al-containing layers is described in more detail in the context of creating DBR structures in our copending application entitled “(Ga,In)(N,As) Laser Structures using Distributed Feedback” and filed concurently herewith.

Thus, the invention provides tuneable semiconductor lasers based on phase control sections containing Bragg gratings (Distributed Bragg Grating regions DBRs). A typical example is a two section DBR laser with frequency control in the DBR section and gain control in a second (grating free) section of the device. Several advantages of the invention also arise from the use of the (Ga,In)(N,As) system, specifically the lower index step between the active region and the confinement layers and the more dilute optical mode that results. This enables a higher output power owing to the reduced saturation which follows from the more diffuse mode.

The application also relates to a tunable semiconductor laser comprising a propagation region in which a waveform can exist, the propagation region comprising sequential gain and control regions, the gain region comprising a light amplification region supplied by a source of excitation, and the control region comprising a periodic structure through which the waveform propagates, wherein the regions are formed in the same epitaxial growth steps and modified by oxidation following completion of the laser structure.

In this way, the laser structure can be grown in a single process without interruption for the periodic structure.

The application further relates to a tunable semiconductor laser comprising a layered structure, at least one layer of which includes a propagation region in which a waveform can exist, the propagation region comprising sequential gain and control regions, the gain region comprising a light amplification region supplied by a source of excitation, and the control region comprising a periodic structure through which the waveform propagates, the confinement of the waveform in the control region in a lateral direction within the layer and transverse to the propagation direction being greater than in the propagation region.

### BRIEF DESCRIPTION OF THE DRAWINGS

Embodiments of the present invention will now be described, by way of example, with reference to the accompanying drawings, in which;

FIG. 1 is a plan view of the layout of a two section tunable DBR laser;

FIG. 2 is a cross-section of a two section DBR laser showing modal confinement in the two regions;

FIGS. 3a and 3b are vertical sections through a ridge comprising the propagation region showing the use of oxidation for introducing increased confinement in the DBR sections;

FIG. 4 is a horizontal section also showing the use of oxidation for introducing increased confinement in the DBR sections; and

FIGS. 5 and 6 are sections on V-V and VI-VI of FIG. 4, respectively.

### DETAILED DESCRIPTION OF THE EMBODIMENTS

A potential advantage of (Ga,In)(N,As) material system for 1.55μm lasers is the reduced refractive index step between active layers and cladding layers. The refractive index of a (In,Ga)(As,P) active region at 1.55μum is n=3.58. A similar index of refraction exists for a 1.55μm (In,Ga)(N,As) active region. The cladding region in the materials systems are InP and GaAs respectively. GaAs has refractive index of n=3.37 at 1.55μm and InP a refractive index of n=3.16 at 1.55μm. The reduced index step in the (Ga,In)(N,As) system allows a less tightly confined mode. In combination with increased differential gain in this materials system, a higher output power can be expected. However, the band gap between the active and cladding layers remains similar, allowing similar electrical behaviour.

A tightly confined mode is required in the grating section of the device. Here the highest possible phase change is required for the smallest change in carrier density. This is to avoid heating effects and excessive losses in the device. Whilst this apparently contradicts benefits of the loose confinement described above, this requirement can be met (for example) through the use of oxidation of Al-containing layers. A suitable layer is Al98Ga02As. In the following, AlAs will be referred to, meaning an Al-rich layer such as this, preferably one with an Al content above 80%. Therefore, the fabrication of the device can be considerably simplified, in that the loose and tight confinement can be achieved using only post process modifications to the same epitaxial layer structure.

The grating may be formed in the conventional manner of etching a grating profile into the semiconductor in the desired locations, then overgrowing to complete the laser structure.

Additionally the grating may be formed by the use of metal gratings, further simplifying the fabrication process.

The grating may be formed by the oxidation through a mask (described in our copending application), further simplifying the process.

The grating so formed may provide the lasing for the gain clamping mechanism in SOAs. An SOA may have an advantageous spot size owing the lower refractive index step.

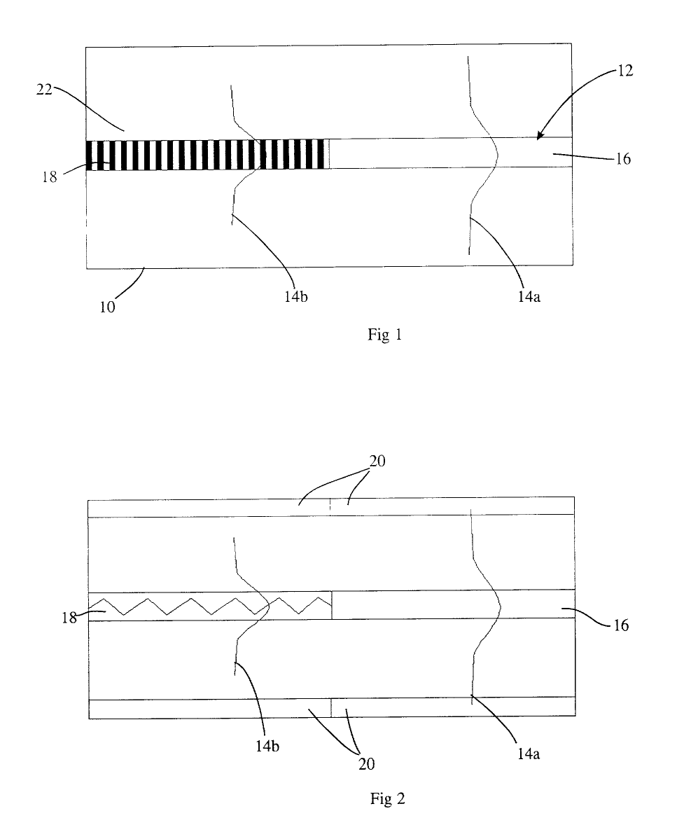

Referring to FIG. 1, a device 10 includes a ridge waveguide 12 in which a waveform 14 propagates. The ridge is divided into two portions; a gain portion 16 and a control portion 18. The gain portion is supplied with a means of excitation by way of electrodes 20 above and below, visible in FIG. 2, and thereby acts as a lasing means to amplify the waveform. The control portion 18 is formed with a periodic structure in order to act as a distributed Bragg reflector (DBR) and thereby select a desired wavelength for the lasing structure. Control electrodes 22 are placed above and below to permit a current to be established in the DBR region. The charge carrier density affects the refractive index, and therefore the current can be used to determine the periodicity “seen” by the waveform and hence the wavelength that is selected.

FIG. 1 includes profiles 14a and 14b of the desired waveform. Profile 14a is in the gain region and occupies a wide volume of material, whereas profile 14b is in the control region and is limited more closely to that region.

FIG. 2 shows a similar view in which a section on the ridge shows the periodic structure of the control region 18. Similar profiles 14a and 14b of the desired waveform are also shown.

As discussed above, it is an advantage of using the (Ga,In)(N,As) system that the refractive index step between that and the cladding layer is lesser and hence confinement in the laser region is looser. This means that the local maxima of the waveform intensity is lower and saturation is less likely. Accordingly a higher gain can be provided and hence a higher output power achieved. However, in the control region there is an apparently conflicting requirement, in that a looser confinement means a more widely spread waveform which “sees” a wider volume of semiconductor. Accordingly, the current density must be applied over a larger volume in order to obtain a variation of refractive index which achieves a specific variation in wavelength. This increases the heating effect of the current, the overall power consumption of the device, and the difficulty in control of currents in the two sections of the device to achieve a given output wavelength.

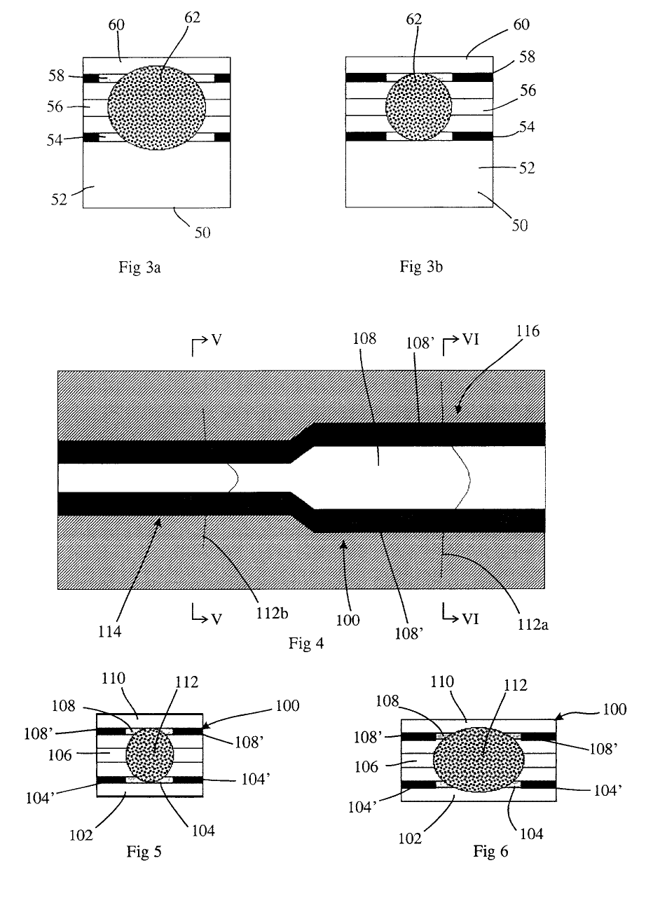

FIGS. 3a and 3b show how tighter confinement of the waveform can be achieved in the control region. The propagation region is contained in a ridge 50 in which the layers of interest are, in order, a base layer 52, a lower AlAs 54 layer covered with a number of (Ga,In)(N,As) layers 56, an upper AlAs layer 58, and a capping layer 60 of any suitable semiconductor material. The waveform 62 propagates mainly in the (Ga,In)(N,As) layers 56 but will extend into adjacent semiconducting layers.

FIG. 3a shows an arrangement for loose confinement, such as in the gain region. Only a brief (or no) exposure of the AlAs layers 54, 58 is permitted and hence only a narrow part of the AlAs layers adjacent the sides of the ridge 50 oxidise to Al₂O₃. As a result, the AlAs layers immediately above and below the (Ga,In)(N,As) layer 56 remain available for propagation of the waveform 62 which can spread into the AlAs layers 54, 58 above and below the (Ga,In)(N,As) layers 56 and also into the capping layer 60 and base layer 52.

FIG. 3b shows a tighter confinement. More exposure of the AlAs layers 54, 58 is permitted and accordingly the resulting Al₂O₃ part thereof extends further into the ridge 50. AlAs remains only in the central part of the layers 54, 58. The restricting effect of the Al₂O₃ intrusions will limit its extent and reduce both its width and its height, as illustrated schematically.

Confinement may also be achieved with further Al containing layers or different thicknesses. This allows greater control over the shape of the optical mode as it becomes more tightly confined.

FIGS. 4 to 6 show an alternative means of confinement. The propagation region is again provided in a ridge 100 but this is of varying width. As with the embodiment of FIGS. 3a to 3c, in this embodiment the ridge comprises a base layer 102, a lower AlAs layer 104, (Ga,In)(N,As) layers 106 in which the waveform 112 principally exists, an upper AlAs layer 108, and a capping layer 110 of any suitable semiconductor material. The AlAs layers 104, 108 are again allowed to oxidise to form Al₂O₃ denoted as 104′ and 108′ respectively, but in this case the extent of oxidation is constant along the length of the ridge 100 and hence provides a fine tuning of the confinement width. This need not be the case, and the approaches of both embodiments could be combined.

The ridge is relatively narrower in the control region 114 than in the gain region 116. Accordingly, the waveform 112 can occupy a wider space in the gain region 116, as shown in FIG. 6. In the control region, the physical constraints of the available semiconducting volume as limited further by the Al₂O₃ layers 104′ and 108′ restrict the waveform to a tighter confinement, as desired. Waveform profiles 112a and 112b are shown in the gain region 116 and control region 114 respectively, illustrating this.

Thus, the present invention provides a laser diode structure which allows good selectivity of wavelength and high gain. In this way, the advantages of the (Ga,In)(N,As) system can be employed more fully, although the principles of the invention can be applied in other material systems.

It will be appreciated that many variations may be made to the above described embodiments without departing from the scope of the present invention. For example, the illustrated embodiments are two section devices whereas devices with three or more sections are common to overcome certain limitations of two section devices and to address other operating and fabrication issues. For example, a phase section without a grating and with a separate electrode can be included between the grating section and the gain section. Such multiple section devices which include the two sections of the present invention are encompassed.

1. A tunable semiconductor laser comprising a (Ga,In)(N,As) propagation region in which a waveform can exist, the propagation region comprising sequential gain and control regions, the gain region comprising a light amplification region supplied by a source of excitation, and the control region comprising a periodic structure through which the waveform propagates.

2. A tunable semiconductor laser according to claim 1 in which the regions are formed in the same epitaxial growth steps.

3. A tunable semiconductor laser according to claim 2 in which the regions are modified by oxidation following completion of the laser structure.

4. A tunable semiconductor laser according to claim 1 in which there is tighter confinement of the waveform in the control region as compared to the gain region.

5. A tunable semiconductor laser according to claim 1 in the form of a layered structure.

6. A tunable semiconductor laser according to claim 5, in which the propagation region exists in a layer thereof, the confinement of the waveform in the control region in a lateral direction within the layer and transverse to the propagation direction being greater than in the propagation region.

7. A tunable semiconductor laser according to claim 1 in which the control region is linked to a source of current thereby to enable changes to be made to the refractive index thereof.

8. A tunable semiconductor laser according to claim 4 in which the physical configuration of the control region provides for confinement of the waveform therein which is greater than the confinement in the gain region.

9. A tunable semiconductor laser according to claim 8 in which the propagation region is formed with a lesser effective transverse width in the control region.

10. A tunable semiconductor laser according to claim 9 in which the propagation region is provided in a ridge structure, the ridge being of lesser width in the control region.

11. A tunable semiconductor laser according to claim 1 in which the propagation region includes non-semiconducting regions to confine the waveform.

12. A tunable semiconductor laser according to claim 11 in which the non-semiconducting layers are oxidised products of formerly semiconducting layers.

13. A tunable semiconductor laser according to claim 11 in which Al-containing layers are included in the propagation region.

14. A tunable semiconductor laser according to claim 13 in which the Al-containing layers are at least partly oxidised to Al₂O₃.

15. A tunable semiconductor laser according to claim 13 in which the propagation region is formed in a ridge structure with the edges of the Al-containing layers exposed.

16. A tunable semiconductor laser according to claim 13 in which at least one of trenches and vias are provided either side of the propagation region.

17. A tunable semiconductor laser according to claim 13 in which a periodic structure of holes are provided alongside the propagation region.

18. A two section tuneable semiconductor laser including phase control in a Distributed Bragg Grating region and gain control in a second grating free section of the device.

19. A tunable semiconductor laser comprising a propagation region in which a waveform can exist, the propagation region comprising sequential gain and control regions, the gain region comprising a light amplification region supplied by a source of excitation, and the control region comprising a periodic structure through which the waveform propagates, wherein the regions are formed in the same epitaxial growth steps and modified by oxidation following completion of the laser structure.

20. A tunable semiconductor laser according to claim 19 in which there is tighter confinement of the waveform in the control region as compared to the gain region.

21. A tunable semiconductor laser comprising a layered structure, at least one layer of which includes a propagation region in which a waveform can exist, the propagation region comprising sequential gain and control regions, the gain region comprising a light amplification region supplied by a source of excitation, and the control region comprising a periodic structure through which the waveform propagates, the confinement of the waveform in the control region in a lateral direction within the layer and transverse to the propagation direction being greater than in the propagation region.

22. A method of fabricating a tunable semiconductor laser, comprising the steps of growing via epitaxy a propagation region comprising sequential gain and control regions, completing the laser structure, and subsequently providing tighter confinement of the waveform in the control region as compared to the gain region by modifying the control region through oxidation of an epitaxially grown layer therein.
